(19) United States
(12) Patent Application Publication
(10) Pub. No.: US 2006/0291595 A1
(43) Pub. Date: Dec. 28, 2006

(54) Communications channel symbol recovery by combining outputs at different decision delays

(76) Inventors: Raja S. Bachu, Des Plaines, IL (US); Michael E. Buckely, Grayslake, IL (US); Kenneth A. Stewart, Grayslake, IL (US); Clint S. Wilkins, Chicago, IL (US)

Correspondence Address: MOTOROLA INC, 600 NORTH US HIGHWAY 45, ROOM AS437, LIBERTYVILLE, IL, 60048-5343, US

(21) Appl. No.: 11/169,027

(22) Filed: Jun. 28, 2005

(51) Int. Cl. H03D 1/04

(52) U.S. Cl. 375/346

(57) ABSTRACT

A method and apparatus for communications channel symbol recovery that improves equalizer performance adds together the log-likelihood ratios (LLRs) of different decision delays rather than using LLRs corresponding only to a single decision delay. A low complexity method comprises, determining an initial coarse delay and a set of fine delays (1003), estimating a training sequence and filter taps set for each fine delay (1007), determining an error function for each fine delay (1009), and linearly combining the filter taps (1013) for determining the symbol estimates (1017).

### CROSS-REFERENCE TO RELATED APPLICATIONS

The present invention is related to: U.S. Pat. App. Pub. No. 2004/0161063 (Pub. Date Aug. 19, 2004) “CHANNEL PARAMETER ESTIMATION IN A RECEIVER,” and U.S. Pat. App. Pub. No. US 2004/0161065 (Pub. Date Aug. 19, 2004) “REDUCING INTERFERENCE IN A GSM COMMUNICATION SYSTEM,” both of which are assigned to the same assignee as the present application, and both of which are hereby incorporated by reference herein.

### FIELD OF THE INVENTION

The present invention relates generally to communication systems, and more particularly to communication system receivers and improved methods and apparatus for providing channel parameter estimation.

### BACKGROUND OF THE INVENTION

Timing synchronization is an essential part of base band receiver signal processing in communications system devices such as Global System for Mobile communications (GSM) terminals. Traditional methods for parameter estimation generally, including timing synchronization (optimal decision delay estimation) and channel estimation in receivers, rely on correlating a received signal burst such as a normal burst, a synchronization burst or the like with a known pattern in the received sequence. In the GSM protocols this known pattern or sequence is often referred to as a midamble or Training Sequence (TS) that is embedded in the central portion of the burst. The traditional timing synchronization or decision delay estimation methods further involve the mathematical minimization of a cost function.

In the various methods, cost functions may be energy of channel taps in a fixed length window or output equalizer signal-to-noise ratio (SNR). Such methods typically determine an error cost function for various hypothesized decision delays and then proceed to calculate an optimal delay, via cost function minimization, for use in reconstructing a signal. Unfortunately these methods, which can be classified as conventional “hard” synchronization methods, do not achieve maximum equalizer performance and are also wasteful of processing.

Advances in Digital Signal Processors (DSPs) and processing have enabled more extensive and complex calculations that have led to additional techniques to improve channel estimation and other relatively complex signal/data conversions. The methods of timing synchronization could therefore be improved significantly through intelligent signal processing.

Thus a need exists for improved, preferably less computationally complex techniques for performing timing synchronization, which would improve overall equalizer performance.

### BRIEF DESCRIPTION OF THE DRAWINGS

FIG. 1 is a diagram illustrating an exemplary communications unit and an input signal burst.

FIG. 2 is a block diagram illustrating the primary components of a mobile station in accordance with some embodiments of the present invention.

FIG. 3 is a diagram illustrating an exemplary approach to channel parameter estimation such as delay estimation.

FIG. 4 is a diagram illustrating an exemplary approach to extraction of an observation or estimation vector.

FIG. 5 is a diagram illustrating a low complexity approach to extraction of an observation or estimation vector.

FIG. 6 is a graph illustrating improvements gained using various embodiments of the present invention.

FIG. 7 is a flow chart illustrating the basic operation of a first embodiment of the present invention.

FIG. 8 is a flow chart showing further details of operation in accordance with the first embodiment of the present invention illustrated by FIG. 7.

FIG. 9 is a flow chart illustrating the basic operation of a second embodiment of the present invention.

FIG. 10 is a flow chart showing further details of operation in accordance with the second embodiment of the present invention illustrated by FIG. 9.

FIG. 11 is a block diagram illustrating an alternative embodiment of the present invention having a receiving configuration with multiple antennas.

### DETAILED DESCRIPTION OF THE PREFERRED EMBODIMENTS

To address the above-mentioned need, a method and apparatus which provides improved equalizer performance is provided herein.

In accordance with a first aspect of the present invention, a receiver combines the log-likelihood-ratios at different decision delays resulting in improved equalizer performance over traditional methods. In accordance with a second aspect of the present invention the complexity of the approach is avoided and reduced by employing a modified computation method that avoids multiple filtering operations while maintaining the same performance of multiple filtering using only a single filtering operation.

In the various embodiments of the present invention, the equalizer outputs associated with two or more different “fine delays,” that is, changes in the reference sample delay at which the data waveform is observed, are combined to obtain a more reliable output than can be obtained by simply retaining the equalizer output for any single hypothesized delay. The various embodiments of the present invention therefore relate to the timing synchronization function in communication system receivers.

The synchronization function is typically divided into two parts: (1) coarse synchronization and (2) fine synchronization. The coarse synchronization function produces a rough estimate of the delay of a received waveform. The fine synchronization function in conventional receivers refines the estimate of delay to produce a single delay which is subsequently used in data symbol estimation. The refined single delay utilized, which is the so-called “optimal” fine time delay, is selected from a range of potential delays around the coarse delay. The optimal delay may, for example, be based on the performance metrics of energy of channel taps in a fixed length window or output equalizer signal-to-noise ratio (SNR).

The fine delay parameter is critical in optimizing both linear, for example Finite Impulse Response (FIR) and non-linear, for example Decision-Feedback Equalizer (DFE) equalizer performance. However, using the embodiments of the present invention, the equalizer output from two or more delays can be combined to obtain a more reliable output than is obtained using conventional methods.

An example of determining and using a fine delay parameter is the alternate linear output equalizer (ALOE) which is a method for demodulating Gaussian Minimum Shift Keying (GMSK) signals. The ALOE demodulation scheme has been described in U.S. Pat. App. Pub. No. US 2004/0161065 (Pub. Date Aug. 19, 2004) “REDUCING INTERFERENCE IN A GSM COMMUNICATION SYSTEM,” which is co-pending and has been previously incorporated herein by reference. An exemplary method of determining the optimal delay for an ALOE is described in U.S. Pat. App. Pub. No. 2004/0161063 (Pub. Date Aug. 19, 2004) “CHANNEL PARAMETER ESTIMATION IN A RECEIVER,” which is likewise co-pending and has likewise been previously incorporated herein by reference.

The method of determining the optimal delay may be summarized as follows. A delay parameter may be determined in general, by comparing the processed symbol sequence, obtained using known or predetermined properties of the received signal, to a predetermined symbol sequence. Examples of known or predetermined properties include; a timing value associated with the signal, a known quadrature phase relationship for symbols in a portion of the received signal, or any other suitable discernable signal properties.

After initial coarse decision delay estimation, a set of N_{d} possible decision delays is established, usually around the coarse delay estimate. For each hypothesized delay, more specifically for each of N_{d} hypothesized fine delays up to the n^{th} fine delay, an error cost function εₙ=∥t−\hat{t}ₙ∥² is calculated, where the vector t is the known midamble. The GSM specifications for example, define a midamble or Training Sequence Code (TSC) embedded in the central portion of the burst, for this purpose. The vector \hat{t}ₙ is the output of a demodulator, for example an ALOE, corresponding to the known midamble/TSC for the n^{th} decision delay.

The optimum delay, herein identified by the variable “n^{†},” is the delay which minimizes εₙ for0≦n<N_{d}. If \hat{d}ₙ_{^{†}} is the vector of data symbols at the output of the ALOE at the optimum delay n^{†}, then the equalizer output vector of log-likelihood ratios (LLRs) input to the channel decoder is given by \hat{d}ⁿ_{^{†}}/εₙ_{^{†}}. This method is referred to as the conventional single-LLR method, and is described in the incorporated references as previously mentioned.

It will be appreciated that estimating parameters and otherwise processing received signals may be performed in a dedicated device such as a receiver having a dedicated processor, a processor coupled to an analog processing circuit or receiver analog “front-end” with appropriate software for performing a receiver function, an application specific integrated circuit (ASIC), a digital signal processor (DSP), or the like, or various combinations thereof, as would be appreciated by one of ordinary skill. Memory devices may further be provisioned with routines and algorithms for operating on input data and providing output such as operating parameters to improve the performance of other processing blocks associated with, for example, reducing noise and interference, and otherwise appropriately handling the input data.

It will further be appreciated that wireless communications units may refer to subscriber devices such as cellular or mobile phones, two-way radios, messaging devices, personal digital assistants, personal assignment pads, personal computers equipped for wireless operation, a cellular handset or device, or the like, or equivalents thereof provided such units are arranged and constructed for operation in accordance with the various inventive concepts and principles embodied in exemplary receivers, and methods for estimating parameters, such as delay parameters, and the combining of such parameters as discussed and described herein.

The principles and concepts discussed and described may be particularly applicable to receivers and associated communication units, devices, and systems providing or facilitating voice communications services or data or messaging services over wide area networks (WANs), such as conventional two way systems and devices, various cellular phone systems including analog and digital cellular, Code Division Multiple Access (CDMA) and variants thereof, Global System for Mobile communications (GSM), General Packet Radio Service (GPRS), 2.5 G and 3G systems such as Universal Mobile Telecommunication Service (UMTS) systems, integrated digital enhanced networks and variants or evolutions thereof. Principles and concepts described herein may further be applied in devices or systems with short range communications capability normally referred to as W-LAN capabilities, such as IEEE 802.11, Bluetooth, or Hiper-LAN and the like that may utilize CDMA, frequency hopping, orthogonal frequency division multiplexing, or TDMA access technologies and one or more of various networking protocols, such as TCP/IP (Transmission Control Protocol/Internet Protocol), IPX/SPX (Inter-Packet Exchange/Sequential Packet Exchange), Net BIOS (Network Basic Input Output System) or other protocol structures.

Further, it is to be understood that while some embodiments of the present invention are applicable to GSM communication systems, other analogous embodiments exist for other burst data communication systems such as IS-54, EDGE , etc., which may successfully employ the beneficial methods disclosed herein.

As described in greater detail hereinafter, various inventive principles are employed to provide a more accurate channel related parameter estimate, such as a delay estimate and symbol estimates, for a receiver and further to provide an improved equalizer output and a reduced computation complexity in deriving such an estimate and equalization from a received signal or associated data stream. Further, the inventive principles disclosed and described herein may be used in conjunction with a variety of methods including alternate linear output equalization (ALOE) as described in the co-pending application noted above, Serial No. 10/366,106, U.S. Pat. App. Pub. No. US 2004/0161065 (Pub. Date Aug. 19, 2004) “REDUCING INTERFERENCE IN A GSM COMMUNICATION SYSTEM.”

As mentioned previously, a delay parameter may be determined by comparison of the processed sample, more specifically a symbol sequence, to a predetermined sample. Further, a set of hypothetical delays for the signal sample may be established based on an initial coarse delay estimate for the received signal.

The received signal estimate may be compared to the predetermined or known sample or sequence to generate a difference value and a delay parameter chosen based on the difference value corresponding to the hypothetical delay. However, in the various embodiments of the present invention, such methods have been modified to improve equalizer performance.

As an example of existing methods, N_{d} hypothetical delays may be established for the signal sample and N_{d} portions of the signal sample extracted. A corresponding signal estimate is determined for each of the hypothetical delays using the extracted portions and the predetermined sample to provide N_{d} corresponding signal estimates. Each of the signal estimates may be compared to the predetermined sample to generate difference values; and the delay parameter chosen as the delay parameter corresponding to the appropriate difference value, typically the smallest difference value.

Alternatively, N_{d} hypothetical delays may be established for the signal sample and a portion of the signal sample extracted corresponding to one of the N_{d} hypothetical delays and N_{d} portions of the predetermined sample. A corresponding signal estimate may be determined for each of the N_{d} hypothetical delays using the N_{d} portions and the portion of the signal sample to provide N_{d} corresponding signal estimates. Each the N_{d} corresponding signal estimates may be compared to the corresponding one of the N_{d} portions of the predetermined or known sample to generate N_{d} difference values. The delay parameter may be chosen based on the hypothetical delay corresponding to a minimum or smallest difference value.

As a further example, Nₛ polyphase signal samples associated with the received signal may be generated by decimating the received signal by a value of Nₛ, where for example Nₛ is the oversampling rate for the received signal. The hypothetical delay value for each of the Nₛ polyphase signal samples may be based on the estimated position of the predetermined sample within the received signal. It should be noted that processing and comparison is typically repeated for each of the Nₛ polyphase signal samples to provide corresponding difference values the parameter chosen corresponding to the delay corresponding to the smallest difference value.

In some embodiments of the present invention, the received signal may be a Gaussian Minimum Shift Keying (GMSK) modulated signal and the receiver may correspondingly include a Global System Mobile (GSM) receiver although the invention can be practiced on other types of signal-system combinations without departing therefrom. The predetermined or known sample and received signal may include a training sequence (TS).

It is to be understood that the use of relational terms, if any, such as first and second, top and bottom, and the like are used solely to distinguish one from another entity or action without necessarily requiring or implying any actual such relationship or order between such entities or actions.

Much of the inventive functionality and many of the inventive principles are best implemented with or in software or firmware programs or instructions and integrated circuits (ICs) such as digital signal processors (DSPs) or application specific ICs (ASICs) as is well known by those of ordinary skill in the art. Therefore, further discussion of such software, firmware and ICs, if any, will be limited to the essentials with respect to the principles and concepts used by the various embodiments.

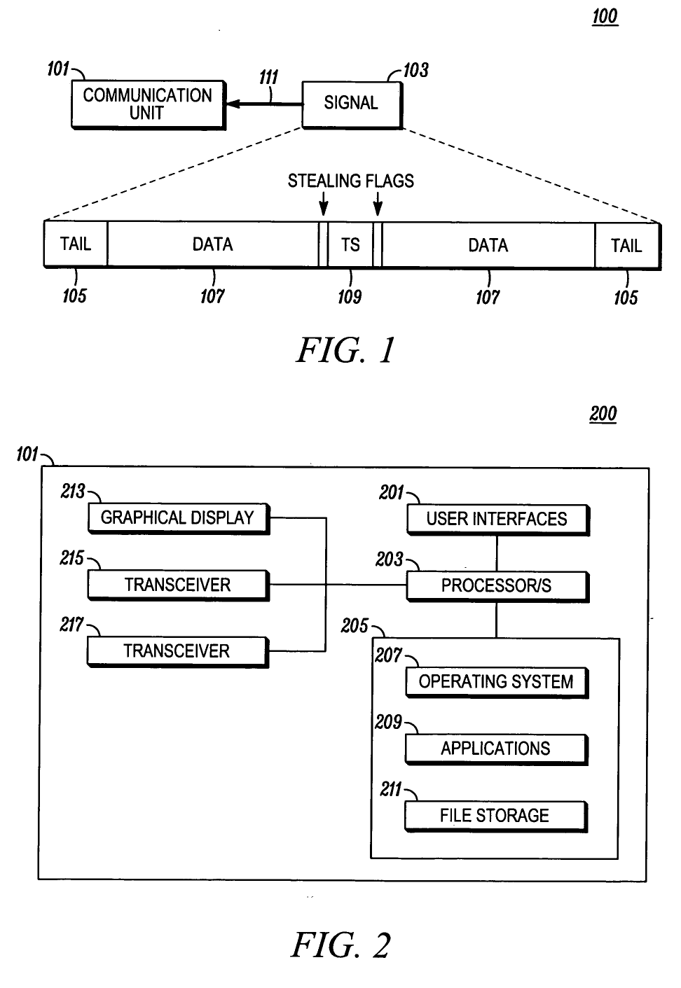

Turning now to the drawings wherein like numerals represent like components, FIG. 1 is a simplified and representative diagram of exemplary scenario 100 having communication unit 101, signal 103, and wireless channel or air interface 111. Exemplary signal 103, in some embodiments, may be a GMSK modulated signal transmitted in a burst, and may further include preambles and postambles, or tails 105 at each end thereof, data sections 107, and a midamble 109, which may further include a sequence known, a priori, such as a training sequence (TS).

Turning now to FIG. 2, the primary components of communication unit 101 in accordance with some embodiments of the present invention are illustrated.

Communications unit 101 comprises user interfaces 201, at least one processor 203, and a memory 205. Memory 205 has storage sufficient for the mobile station operating system 207, applications 209 and general file storage 211. Communications unit 101 user interfaces 201 may be a combination of user interfaces including but not limited to a keypad, touch screen, voice activated command input, and gyroscopic cursor controls.

Communications unit 101 has a graphical display 213, which may also have a dedicated processor and/or memory, drivers etc. which are not shown in FIG. 2. It is to be understood that FIG. 2 is for illustrative purposes only and is for illustrating the main components of a mobile station in accordance with the present invention, and is not intended to be a complete schematic diagram of the various components required for a mobile station. Therefore, a mobile station may comprise various other components not shown in FIG. 2 and still be within the scope of the present invention. For example, components for performing analog-to-digital conversion or other conditioning, or decoding, etc. of the incoming signal or samples of such signals may be allocated or otherwise distributed throughout several sections within communication unit 101.

Returning to FIG. 2, the mobile station 200 also comprises a number of transceivers such as transceivers 215 and 217. Transceivers 215 and 217 may be for communicating with various wireless networks using for example one or more of 802.11, Bluetooth™, IrDA, HomeRF, GSM, CDMA, CDMA2000, UMTS, IS-54, EDGE, etc., and receiving or transmitting a signal such as signal 103 via one or more antennas (not shown).

Further, the mobile station 200 may comprise two or more antennas (not shown), and a transceiver or various configurations of transceivers for using the two or more antennas, for the purpose of communicating with one specific network, for example a GSM network.

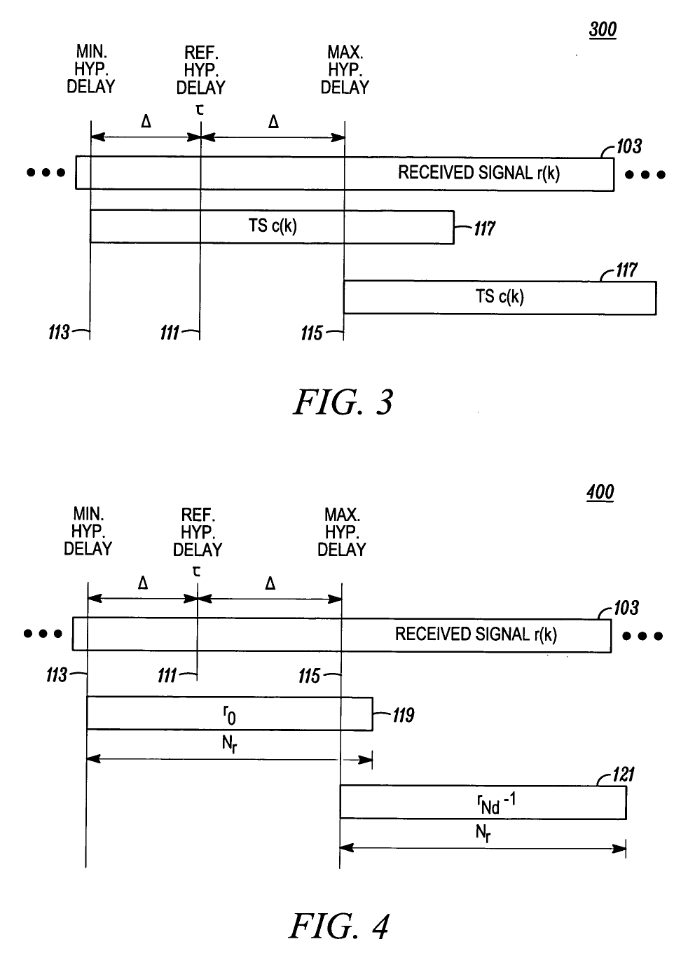

An exemplary approach to channel parameter estimation such as delay estimation, is shown in FIG. 3. Reference hypothetical delay 111 represents an initial coarse delay estimate and may be for example, an estimated or arbitrary value set for an arrival time associated with received signal 103. It should be noted that the reference value for hypothetical delay 111 may be arbitrarily chosen as the beginning of a known sequence such as, for example, a 26-symbol TS known a-priori to occur within ±Δ, − at 113 and + at 115 of the reference delay r established at hypothetical delay 111. In practice the estimated or reference delay T may be chosen as the last estimate for this delay, for example from the previous input signal burst 103.

In one known approach or scheme for channel estimation or equalization, a complex conjugate c*(k) of the known sequence such as the 26-symbol TS sequence c(k) 117 may be correlated with the received signal r(k) 103 over a number 2ΔNₛ/Tₛ+1 of delays after appropriate complex rotation of c*(k) to emulate the GMSK modulation process, where Tₛ is the symbol interval, and Nₛ is the over-sampling factor. A length -2ΔNₛ/Tₛ+1 vector Γ of correlation results is thus formed. If communication unit 101 is subsequently designed to operate using symbol-rate sampling, the optimal delay may be computed by identifying the length-L symbol rate sampling vector φₙ associated with elements extracted from Γ with the maximum norm, where L is the maximum channel impulse response length, for example 5 symbols, for which the subsequent detector is designed, and where φₙ is obtained by decimating by Nₛ—i.e. φₙ(m)=Γ(n+mNₛ), for 0≦m<L.

In the co-pending application noted above, U.S. Pat. App. Pub. No. US 2004/0161065 (Pub. Date Aug. 19, 2004) “REDUCING INTERFERENCE IN A GSM COMMUNICATION SYSTEM,” a method is described for improving the reception of GMSK signals in the presence of interfering signals, such as other GMSK signals generating on-channel interference, the method termed Alternate Linear Output Equalizer (ALOE). Applying many of essentially the same techniques for ALOE, the quality or accuracy of the optimum delay estimate for a received signal at a receiver can be significantly improved over the classical correlation method described above. Various techniques are utilized to reduce noise or other on channel interference and thereby improve the estimate for the delay or other associated parameter.

One method for computing an optimal reference delay value for an ALOE or any other receiver begins by providing a signal sample corresponding to the received signal. This may comprise decimating a received signal r(k) 103 by a factor Nₛ to generate Nₛ polyphase signals sampled at the symbol rate. For example, the received signal is oversampled at a rate of 2, i.e. Nₛ=2, and decimation amounts to collecting every other sample for a first polyphase signal with the other samples collected for a second polyphase signal. Given the signal sample it is processed to suppress on channel interference and provide a processed sample. This processing relies on known properties of the received signal to suppress on channel interference and these properties may comprise a known quadrature phase relationship for a predetermined set of symbols in a portion of the received signal, specifically the TS in the figures although any other known sequence with known and similar properties could be utilized. For example the TS used in GSM systems employing GMSK modulation is comprised of 26 symbols where the symbols alternate between wholly imaginary and real symbols with imaginary symbols alternating between −j and +j and real symbols alternating between +1 and −1, e.g. −j, +1, j, −1, −j, . . . for a sequence of 26 symbols.

The processing of the signal sample includes establishing a hypothetical delay for the signal sample based on an estimated delay for the signal, processing the received signal to provide a received signal estimate using the hypothetical delay, the signal sample, and the predetermined or known sample or sequence, comparing the received signal estimate to the predetermined sample to generate a difference value, and selecting or choosing the delay parameter based on the difference value corresponding to the hypothetical delay used to provide the difference value. To provide a choice or selection of difference values and thus choice of a delay parameter a plurality of delays or hypothetical delays are typically used.

Establishment of the hypothetical delay may further comprise, for each polyphase signal, a set of N_{d}=2Δ/Tₛ+1 delays established over the region τ±Δ as noted before from a reference delay for example set at hypothetical delay 111, to − at 113 and + at 115. The range for the hypothetical delays will depend on system and channel characteristics and can be experimentally determined.

However, satisfactory results have been obtained where the range was +/−2 symbol time periods. It will be appreciated that each delay corresponds to the hypothesized start of the TS sequence c(k) 117 in received signal r(k) 103, and for each delay 0≦n<N_{d} an associated observation vector rₙ is extracted as shown, for example in FIG. 4, as vector r₀ 119 and vector r_{Nd-1} 121, each of length Nᵣ. Extracting the vectors r amounts to selecting the samples from the signal sample or specifically one of the polyphase signals corresponding to the Nᵣ samples beginning at the corresponding hypothetical delay.

For each hypothesized delay n, an ALOE solution vector may then be computed as described in co-pending application U.S. Pat. App. Pub. No. US 2004/0161065 (Pub. Date Aug. 19, 2004) “REDUCING INTERFERENCE IN A GSM COMMUNICATION SYSTEM.” That is, successive real and imaginary parts of the output of a length-L linear estimator may be compared to successive real and imaginary parts of TS sequence c(k) 117. More precisely, given that the TS sequence c(k) 117 includes a length-26 modified TS vector t=[t₁(0), tᵣ(1), t₁(2), tᵣ(3) . . . , tᵣ(25)]^{T}, where tᵣ(m) and t₁(m) are the real and imaginary components respectively of the m-th TS symbol (hence the vector t is wholly real valued), the ALOE solution vector is the optimal linear estimator weight vector wₖ^{†} or that vector which minimizes the difference value or error εₙ=∥t−\hat{t}ₙ∥², where \hat{t}ₙ is the signal estimate (real valued) corresponding to the nth hypothetical delay and is based on the length-Nᵣ observation vector rₙ(Nᵣ=L+26−1).

L is the channel delay spread or more specifically the delay spread for the channel that the processing system is able to model. A value of 5 symbol times has been previously found to be appropriate. As noted above rₙ is extracted from received signal r(k) 103 starting at the n-th reference value for hypothetical delay 111 according to FIG. 3 and FIG. 4 and from above will be comprised of 30 adjacent samples. Thus a signal estimate \hat{t}ₙ corresponding to each of the hypothetical delays has been determined and each of these signal estimates may be compared to the known or predetermined sample t to generate the N_{d} difference values according to εₙ=∥t−\hat{t}ₙ∥². The best estimate for the delay parameter is then chosen as the hypothetical delay corresponding to the smallest error or difference value using such known methods.

It should be noted that the computation of \hat{t}ₙ may be accomplished by further decomposing vector rₙ into a sequence of length-L column observation vectors y(n) and computing \hat{t}ₙ according to Equation (1):

$${\hat{t}}_{n} = [ \begin{matrix}{y}_{i}^{T} ( 0 ) & - {y}_{r}^{T} ( 0 ) \\ {y}_{r}^{T} ( 1 ) & {y}_{i}^{T} ( 1 ) \\ ⋮ & ⋮ \\ {y}_{r}^{T} ( 25 ) & {y}_{i}^{T} ( 25 )\end{matrix} ] [ \begin{matrix}{w}_{r}^{+} \\ {w}_{i}^{+}\end{matrix} ] □ {Z}_{n} w \qquad EQ ( 1 )$$

where yᵣ(m) and yᵢ(m) denote respectively the real and imaginary part of y(m). Thus yₗ(0) transpose is the imaginary parts of the first L=5 samples or if sampled at the symbol rate first L symbol observations, e.g. observations 0, 1, 2, 3, 4 of the vector rₙ. Thus the matrix with the y vectors is a 26 by 10 matrix and this matrix is defined as the Z matrix. The ALOE solution vector w is composed of 10 elements, e.g. 5 real and 5 imaginary elements. Accordingly, optimum delay n^{†} may be identified as that delay which minimizes εₙ for 0≦n<N_{d}. In the case Nₛ>1, the optimum delay would be extracted from the polyphase signal with the smallest value of εⁿ.

A low complexity method arises from dependency of Zₙ for example as shown in Equation (1) on n, and the need as discussed above to compute the weight vector w associated with each hypothesized delay in order to generate εₙ and in turn, the optimization of ∥t−\hat{t}ₙ∥² over w. This can be accomplished by conventional least-squares methods, so that:
Wₙ^{†}=(Zₙ^{H}Zₙ)⁻¹Zₙ^{H}t EQ (2)

It can be appreciated that the computation of each εₙ and thus a version of \hat{t}ₙ requires a new matrix inversion operation as the matrix Zₙ is updated according to the hypothesized delay n or in accordance with the vector rₙ thus requiring NₛN_{d} matrix inversions which as can be appreciated can be computationally expensive and sometime computationally prohibitive.

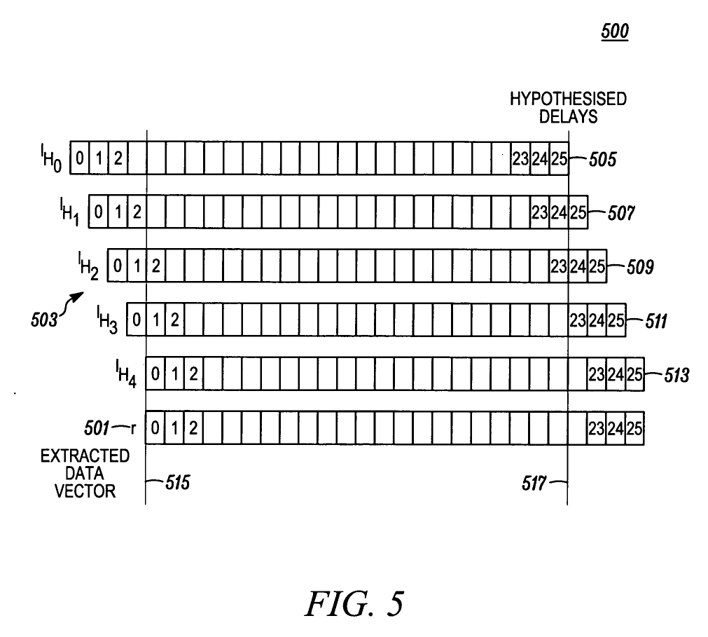

Therefore, a suitable low complexity approach is illustrated by FIG. 5. Therein, vector r 501 may be extracted once and only once from each of the polyphase signals corresponding to received signal r(k) 103. It is to be noted that for the particular example illustrated by FIG. 5, Δ=2Tₛ, a single polyphase is shown associated with for example, vector r 501, and the method is repeated for each polyphase signal generated in the decimation process as described. For each of the N_{d} hypothesized delays and associated sequences 505-513, where, as shown in the example, N_{d}=5, a sub-sequence or portion of the TS corresponding to the n-th hypothesized delay is denoted t_{H}_{ₙ} 503, and is extracted as illustrated. It can be seen that the operative portion of t_{H}_{ₙ} 503 corresponds to the portion of each sequence between time references 511 and 517.

Thus the Zₙ matrix can be populated using the portion of the vector r, namely samples 0-21 and thus the matrix will be a 22 by 10 matrix with L=5. The w^{†} vector can be calculated from EQ (2) by substituting the appropriate t_{H} for the corresponding delay, where t_{H} corresponds to the portion of the TS between the time references 511 and 517. Given the w^{†}vector EQ (1) can be used to determine the signal estimate for each hypothesized delay and the revised error metric or difference value εₙ=∥t_{H}_{ₙ}−\hat{t} _{H}_{ₙ}∥² can be generated by comparing the known or predetermined sample or portion thereof to the corresponding signal estimate. Note that for each polyphase signal only one matrix inversion is required.

Thus the alternative approach referred to above comprises establishing an initial hypothetical delay for the signal sample, which is a coarse delay estimate, and further establishing a set of N_{d} hypothetical delays for the signal sample. Processing the received signal to provide the received signal estimate further comprises: extracting a portion of the signal sample r 501 corresponding to one of the N_{d} hypothetical delays and N_{d} portions 503 of the predetermined sample or known sequence, where one portion 505-513 corresponds to each of the N_{d} hypothetical delays and determining a corresponding signal estimate for each of the N_{d} hypothetical delays, using the N_{d} portions and the portion of the signal sample to provide N_{d} corresponding signal estimates. Comparing the received signal estimate further comprises comparing each of the N_{d} corresponding signal estimates to the corresponding one of the N_{d} portions of the predetermined sample or known sequence to generate N_{d} difference values; and choosing the delay parameter for the received signal further comprises choosing that hypothetical delay which corresponds to the smallest difference value. Note that this simplified approach can also be used for determining, for example filter weights for a channel equalization filter, such as discussed in the above identified co-pending application, to further reduce computational complexity.

Turning now to the enhanced methods provided by the embodiments of the present invention, the log-likelihood ratios (LLRs) of different hypothesized delays are added together instead of simply using the LLRs corresponding only to a single hypothesized delay, which minimizes the error metric, as in the methods previously discussed. For example, if \hat{d}ₙ represents the output vector of an ALOE at decision delay n, i.e. the optimized symbol estimation vector, then the vector of log-likelihood ratios input to the channel decoder is given by the summation equation

$${\sum }_{t}^{{N}_{d}} {\hat{d}}_{n} / {ɛ}_{n} .$$

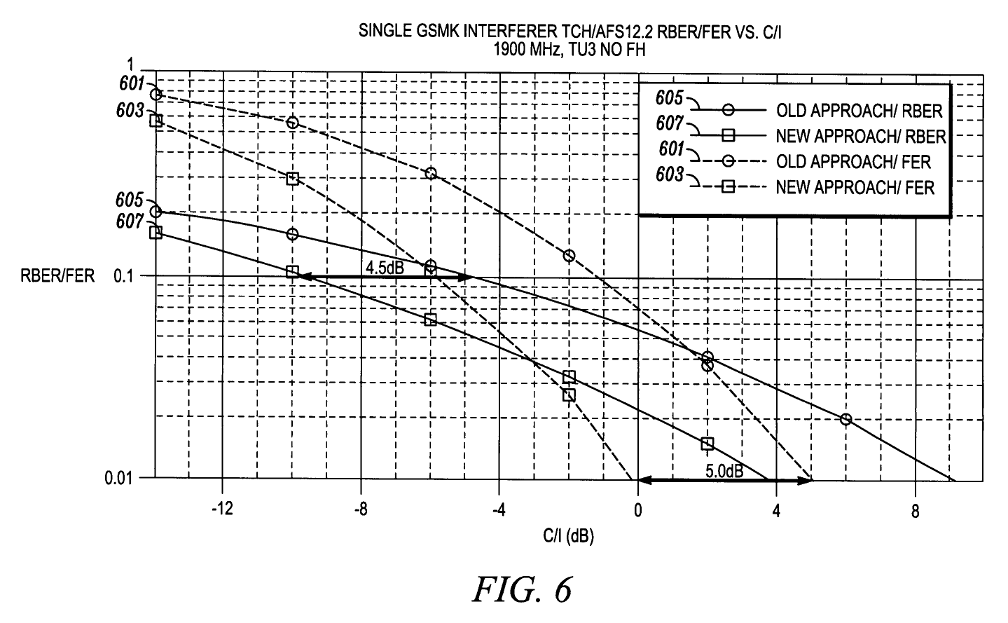

Thus in the embodiments of the present invention, a number of ALOE output vectors, or symbol estimation vectors, at various fine delays are combined with weights equal to the inverse of the cost function, i.e. the error metric used in previous methods. The performance of the approach provided by the embodiments of the present invention herein described compared to the conventional single-LLR method is shown in FIG. 6. The results illustrated by FIG. 6 are for a single GMSK co-channel interferer operating on the AMR 12.2 kbps logical channel and for typical urban channel conditions as specified in ETSI standards. The number of hypothesized delays is N_{d}=5.

The horizontal axis of FIG. 6 represents carrier-to-interference (C/I) ratios in decibels (dB) whilst the vertical axis represents either raw bit error rate (RBER) or frame erasure rate (FER) depending upon the curve under consideration. Curves 601 and 603 provide a comparison of FER for single LLR methods with the method of embodiments of the present invention respectively. Similarly, curves 605 and 607 provide a comparison of RBER for single LLR methods with the method of embodiments of the present invention respectively.

It can be seen from FIG. 6 curves 605 and 607 that the method and apparatus of the present invention produces an improvement of approximately 4.5 dB, at the 10% RBER point, over conventional receivers. Likewise illustrated in FIG. 6 by curves 601 and 603 is an improvement of approximately 5 dB, at the 1% FER point, over conventional receiving equipment for the same conditions.

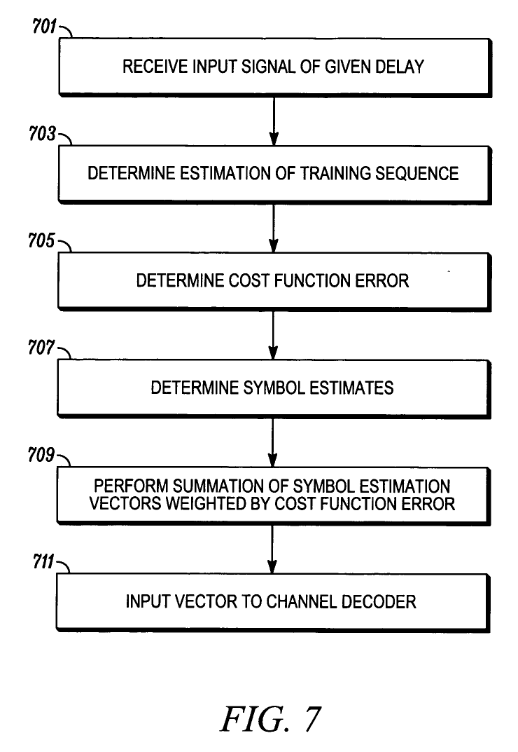

Turning now to FIG. 7, the basic operation of a first embodiment of the present invention is illustrated in block diagram format. Initially, a receiver receives a signal burst 103 having a given characteristic delay as shown in block 701. In block 703, a training sequence is estimated based on the given delay. The training sequence estimation may comprise determining an initial coarse delay estimate for the received signal burst, and determining a number of fine delays around the coarse estimate. In block 705 the error cost function is obtained as the square of the absolute value of the difference of an a priori known training sequence and the estimated training sequence vector from block 703. Symbol estimates are computed as shown in block 707, and may result in a set of symbol estimation vectors wherein each symbol estimation vector corresponds to a hypothetical fine delay.

Summation of the symbol estimation vectors is then performed with weights equal to the inverse ratio of the error cost function as illustrated by block 709 and thus input to the channel decoder as shown in block 711. It is to be understood that the summation of block 709 may be concurrent with determination of the symbol estimation vectors of block 707 and that the diagram of FIG. 7 is for illustrative purposes only of the overall and basic functionality of the various embodiments of the present invention and is not to be taken as indicative of the precise order of events.

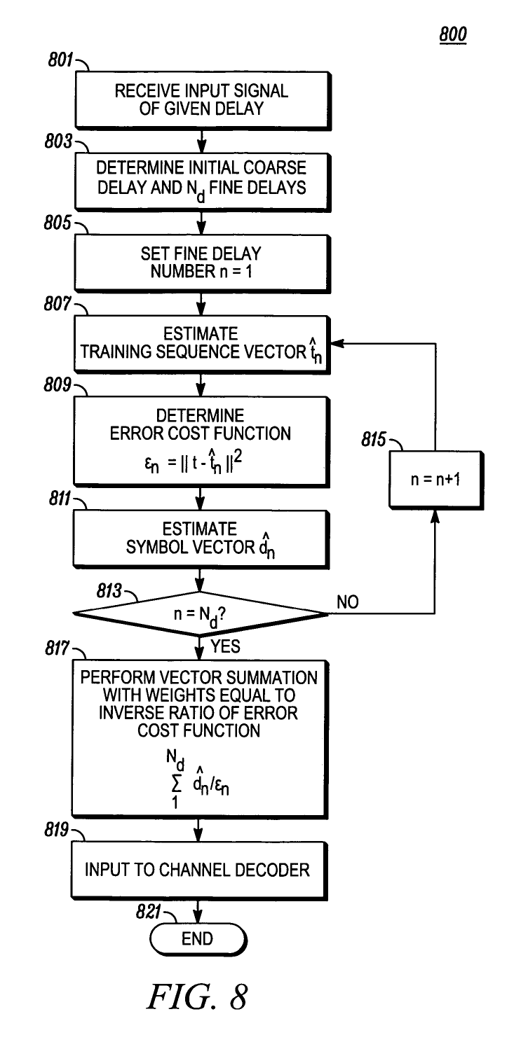

FIG. 8 is a flow chart showing further details in accordance with some embodiments of the present invention. Block 801 represents receiving a signal 103 having a training sequence 109. In block 803, an initial coarse delay estimate is determined and a number of hypothetical fine delays, more particularly N_{d} fine delays, are hypothesized around the initial coarse delay estimate. In block 805 , “n”—the hypothesized fine delay number is initialized to 1. The total number of hypothesized fine delays is the integer value “N_{d}” and a looping operation begins from a first delay estimation up to “N_{d}” estimations, where the subscript “n” is the designation number for the particular hypothesized fine delay and its corresponding particular iteration.

In block 807, an estimate of the training sequence vector is determined based on the n^{th} hypothesized fine delay. In block 809, an error cost function is computed using the training sequence vector estimated in block 807. For example, the hypothesized fine delay utilized in blocks 805, 807, and 809 may be the fine delay estimation output of an ALOE as described previously. In block 811 a symbol estimation vector is determined for the same delay. In 813 and 815, the looping operation proceeds for N_{d} iterations until n=N_{d}, the maximum predetermined number of hypothesized delays.

In block 817, the symbol vectors are summed with weights equal to the inverse of the error cost function. The error cost function for example, may be as shown in block 809, more particularly the absolute value of the square of the difference between an a priori known training sequence and a corresponding training sequence estimation vector. In 819 the result is input to the channel decoder and the process, routine, sub-routine, etc. as determined by the particular embodiment ends in block 821.

It is important to note that only a modest increase in complexity over conventional methods is necessary for implementation of the embodiments of the present invention. For example in some embodiments, given an ALOE, all N_{d} sets of filter taps that result may be linearly combined prior to filtering rather than filtering N_{d} times. Therefore, the only increase in complexity required by embodiments of the present invention results from equalizing with the slightly longer linearly combined equalizer rather than the single filter at the optimal hypothesized delay as is done in conventional methods.

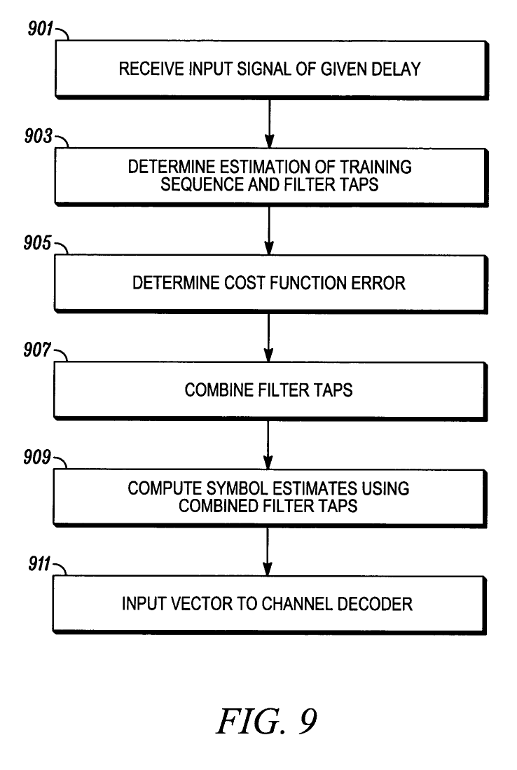

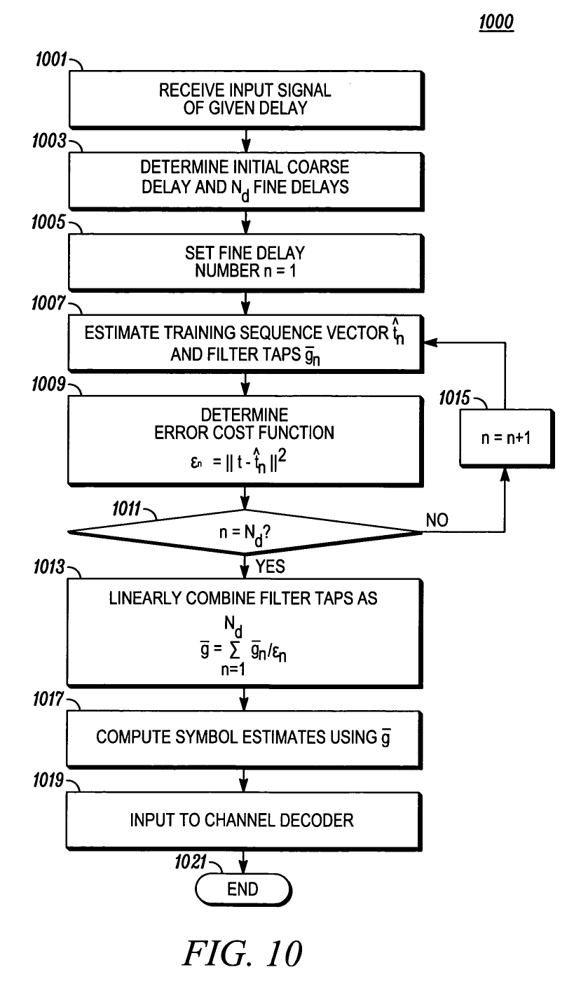

This lower complexity approach is illustrated in FIGS. 9 and 10. After receiving a signal of a given characteristic delay in block 901, a training sequence vector is estimated and also a set of filter taps as shown in block 903. The training sequence vector and filter tap estimation may comprise determining an initial coarse delay estimate for the received signal burst, and determining a number of fine delays around the coarse estimate. The error cost function may be determined as shown in block 905. For the lower complexity approach, the filter taps are linearly combined first as shown in block 907, after which the symbol estimates may be computed using the single filter operation, rather than filtering N_{d} times, as shown in block 909.

FIG. 10 provides further details of the embodiment illustrated by FIG. 9. After receiving a signal of a given delay as in block 1001, an initial coarse delay estimate is determined and a number of hypothetical fine delays, more particularly N_{d} fine delays, are hypothesized around the initial coarse delay estimate as shown in block 1003. In block 1005, “n”—the hypothesized fine delay number is initialized to 1. Similar to FIG. 8, the total number of hypothesized fine delays in FIG. 10 is the integer value “N_{d},” and a looping operation begins from a first delay estimation up to “N_{d}” estimations, where the subscript “n” is the designation number for the particular hypothesized fine delay and its corresponding particular iteration. In block 1007, a training sequence vector is estimated and also a set of filter taps defined as “\overline{g}ₙ,” in which the subscript “n” corresponds to the particular hypothesized fine delay. The error cost function may then be determined in block 1009 based upon the training sequence vector estimate of block 1007 for the particular hypothesized fine delay. Blocks 1011 and 1015 illustrate that the looping operation may continue for N_{d} iterations until training sequence vectors and corresponding filter tap sets are computed for all N_{d} hypothetical delays. In block 1013, a new extended filter may be determined by linearly combining the filter tap sets to obtain “\overline{g}” as illustrated by the block 1013 exemplary summation equation

$${\sum }_{n = 1}^{{N}_{d}} \frac{\overline{{g}_{n}}}{{ɛ}_{n}} .$$

The symbol estimates may then be determined using the new extended filter as defined by \overline{g}, as illustrated in block 1017.

Thus methods and apparatus for advantageously using determined channel parameters by combining such parameters prior to channel decoding to provide an improved symbol estimation thereby improving overall equalizer performance and the like have been disclosed. These methods and apparatus may be advantageously used in or embodied or configured in receivers, such as GSM receivers or communications units, such as cellular telephones and similar devices. One apparatus embodiment includes a conventional receiver front end for providing a received signal and a processor, for example a DSP and supporting functionality that is configured to implement the various functions noted above.

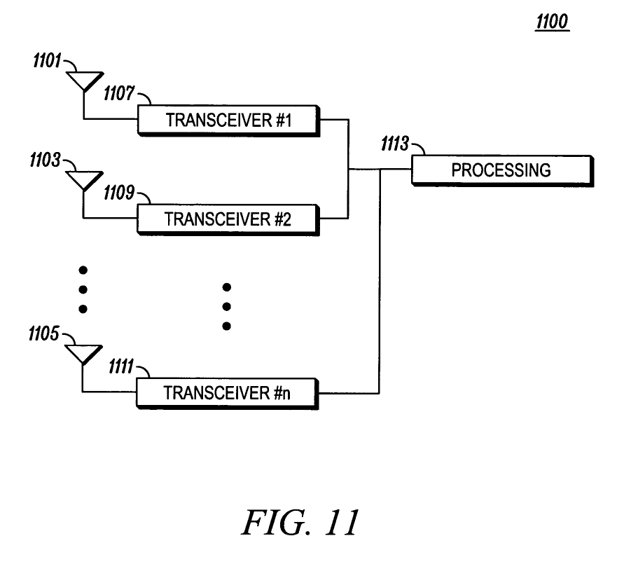

It is to be understood that embodiments having various antenna configurations may use the embodiments of the present invention disclosed herein. For example, receiving systems may have single or multiple antennas. While the various embodiments may be utilized by receivers employing a single antenna, an exemplary configuration employing multiple antennas is illustrated in FIG. 11. A receiving system may employ multiple antennas up to “n” antennas as shown by first antenna 1101, second antenna 1103, and n^{th} antenna 1105. Likewise, in some embodiments, each antenna may have corresponding receiver/transceiver equipment as shown by first transceiver 1107, second transceiver 1109, and n^{th} transceiver 1111. One or more processors may be utilized to perform the operations of the various embodiments of the present invention, as illustrated by processing 1113. Each single antenna may receive a signal having a corresponding delay. It will be apparent to one of ordinary skill in the art that the various embodiments exemplified in FIGS. 7, 8, 9, and 10, may be utilized by the configuration illustrated by FIG. 11, to determine symbol estimates from the received signals.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

What is claimed is:

1. A method of operating a wireless receiver comprising:
receiving an input signal of a given delay; and
determining a channel decoder input as a summation of a plurality of estimated symbol vectors wherein each of said estimated symbol vectors corresponds to a hypothetical delay.

2. The method of claim 1 further comprising, after the step of receiving an input signal of a given delay, the steps of:
determining a set of hypothetical delays based upon said given delay;
determining a set of training sequence vectors by estimating a training sequence vector for each hypothetical delay of said set of hypothetical delays; and
determining a set of error cost function values using and corresponding to said set of training sequence vectors.

3. The method of claim 2, wherein determining a channel decoder input as a summation further comprises weighting each estimated symbol vector of said plurality of estimated symbol vectors using corresponding values from said set of error cost function values.

4. The method of claim 3 wherein said input signal is a Gaussian Minimum Shift Keying (GMSK) modulated signal.

5. The method of claim 4 wherein said receiver is a Global System for Mobile Communications (GSM) receiver.

6. A mobile station comprising:
a receiver; and
at least one processor connected to said receiver and configured to determine an estimated symbol vector as a summation of a plurality of estimated symbol vectors wherein each of said estimated symbol vectors corresponds to a hypothetical delay.

7. The mobile station of claim 6 wherein said at least one processor is further configured to:
determine a set of hypothetical delays based upon an initial delay estimate;
determine a set of training sequence vectors by estimating a training sequence vector for each of said set of hypothetical delays; and
determine a set of error cost function values using and corresponding to said set of training sequence vectors.

8. The mobile station of claim 7 wherein said summation further comprises weighting each estimated symbol vector of said plurality of estimated symbol vectors using corresponding values from said set of error cost function values.

9. The mobile station of claim 8 wherein said receiver is a Global System for Mobile Communications (GSM) receiver.

10. The mobile station of claim 9 wherein said receiver is configured to receive a Gaussian Minimum Shift Keying (GMSK) modulated signal.

11. A method of operating a wireless receiver comprising:
receiving an input signal of a given delay; and
determining a set of filter taps as a summation of a plurality of filter tap sets, each filter tap set corresponding to a hypothetical delay.

12. The method of claim 11 further comprising, after the step of receiving an input signal of a given delay, the steps of:
determining a set of hypothetical delays based upon said given delay;
determining a set of training sequence vectors by estimating a training sequence vector for each hypothetical delay of said set of hypothetical delays; and
determining a set of filter taps corresponding to each hypothetical delay of said set of hypothetical delays.

13. The method of claim 12 further comprising, prior to the step of determining a set of filter taps as a summation of a plurality of filter tap sets, each filter tap set corresponding to a hypothetical delay, the step of:
determining a set of error cost function values using and corresponding to said set of training sequence vectors.

14. The method of claim 13, wherein determining a set of filter taps as a summation of a plurality of filter tap sets further comprises weighting each filter tap set of said plurality of filter tap sets using corresponding values from said set of error cost function values.

15. The method of claim 14 wherein said input signal is a Gaussian Minimum Shift Keying (GMSK) modulated signal.

16. The method of claim 15 wherein said receiver is a Global System for Mobile Communications (GSM) receiver.

17. A mobile station comprising:
a receiver; and
at least one processor connected to said receiver and configured to determine a set of filter taps as a summation of a plurality of filter tap sets, each filter tap set corresponding to a hypothetical delay.

18. The mobile station of claim 17 wherein said at least one processor is further configured to:
determine a set of hypothetical delays based upon an initial delay estimate;
determine a set of training sequence vectors by estimating a training sequence vector for each of said set of hypothetical delays; and
determine a set of filter taps corresponding to each hypothetical delay of said set of hypothetical delays.

19. The mobile station of claim 18 wherein said at least one processor is further configured to:
determine a set of error cost function values using and corresponding to said set of training sequence vectors. 20.The mobile station of claim 19 wherein said summation further comprises weighting each filter tap set of said plurality of filter tap sets using corresponding values from said set of error cost function values.

21. The mobile station of claim 20 wherein said receiver is a Global System for Mobile Communications (GSM) receiver.

22. The mobile station of claim 21 wherein said receiver is configured to receive a Gaussian Minimum Shift Keying (GMSK) modulated signal.
